(19) United States
(12) Patent Application Publication
(10) Pub. No.: US 2025/0143016 A1
(43) Pub. Date: May 1, 2025

(54) SEMICONDUCTOR LIGHT-EMITTING DEVICES

(71) Applicant: ANHUI GAN SEMICONDUCTOR CO., LTD., Lu'an (CN)

(72) Inventors: Shuiqing LI, Lu'an (CN); Jinjian ZHENG, Lu'an (CN); Jiabin LAN, Lu'an (CN); Zhiyong HU, Lu'an (CN); Wanjun CHEN, Lu'an (CN)

(73) Assignee: ANHUI GAN SEMICONDUCTOR CO., LTD., Lu'an (CN)

(21) Appl. No.: 18/399,793

(22) Filed: Dec. 29, 2023

Related U.S. Application Data
(63) Continuation of application No. PCT/CN2023/134956, filed on Nov. 29, 2023.

(30) Foreign Application Priority Data
Oct. 25, 2023 (CN) 202311387387.6

(51) Int. Cl. H01L 33/06; H01L 33/30

(52) U.S. Cl. CPC H10H 20/812; H10H 20/824

(57) ABSTRACT

Semiconductor light-emitting devices are provided, which includes a substrate, a Negative-type semiconductor, a quantum well, an electron-blocking layer, and a Positive-type semiconductor arranged in a sequential stack. The quantum well includes a first quantum well, a second quantum well, and a third quantum well. Optical parameters of the first quantum well, the second quantum well, and the third quantum well are distributed in a gradient in at least one direction. The quantum well includes a periodic structure consisting of a well layer and a barrier layer. A coefficient of thermal expansion of the well layer is smaller than or equal to that of the barrier layer. An elastic coefficient of the well layer is smaller than or equal to that of the barrier layer. A lattice constant of the well layer is greater than or equal to that of the barrier layer. A coefficient of spontaneous polarization of the well layer is smaller than or equal to that of spontaneous polarization of the barrier layer.

### CROSS-REFERENCE TO RELATED APPLICATIONS

This application is a Continuation of International Application No. PCT/CN2023/134956, filed on Nov. 29, 2023, which claims priority to Chinese Patent Application No. 202311387387.6, filed on Oct. 25, 2023, the entire contents of each of which are hereby incorporated by reference.

### TECHNICAL FIELD

The present disclosure relates to the technical field of semiconductor optoelectronic devices, and in particular, to a semiconductor light-emitting device.

### BACKGROUND

Semiconductor optoelectronic devices, especially semiconductor light-emitting devices, have a characteristic such as a wide range of adjustable wavelength, high luminous efficiency, energy saving, environmental protection, a long service life of more than 100,000 hours, a small size, many application scenarios, strong designability. The semiconductor light-emitting devices have gradually replaced incandescent lamps and fluorescent lamps as light sources for general household lighting and are widely used in new scenarios, such as indoor high-resolution display screens, outdoor display screens, Mini-Light Emitting Diodes (LEDs), Micro-LEDs, mobile phone and TV backlighting, backlighting, street lights, automotive headlights, car daytime running lights, car ambient lights, flashlights, or other application fields.

Conventional nitride semiconductors use commonly substrate growth manners, which easily causes large lattice mismatch and thermal mismatch, leads to relatively high defect density and polarization effect, reduces the light-emitting efficiency of the semiconductor light-emitting device. Meanwhile, a hole ionization efficiency of the conventional nitride semiconductors is much lower than an electron ionization efficiency, which results in a hole concentration being at least one order of magnitude lower than an electron concentration. Excess electrons overflow from multiple quantum wells to a second conductive semiconductor to generate non-radiative recombination. The low hole ionization efficiency makes it difficult to efficiently inject holes of the second conductive semiconductor into the multiple quantum wells, which leads to the low light-emitting efficiency of the multiple quantum wells. Furthermore, the nitride semiconductor structure has non-central symmetry, which produces strong spontaneous polarization along the c-axis direction. The spontaneous polarization and a piezoelectric polarization effect of the lattice mismatch may be superimposed to form an intrinsic polarization field. The intrinsic polarization field along the crystal c-axis direction causes a strong quantum confinement Stark effect in the multiple quantum well layers, which results in tilting of energy band and the spatial separation of an electron-hole wave function, reduces the electron-hole radiative recombination efficiency. A parameter of the semiconductor light-emitting device such as a refractive index or a dielectric constant is greater than that of air, which results in a small total reflection angle and low light extraction efficiency when the light emitted from the quantum well is outgoing.

Therefore, it is desirable to provide a semiconductor light-emitting device to improve the luminescence efficiency and quality of the semiconductor light-emitting device.

### SUMMARY

One of the embodiments of the present disclosure provides a semiconductor light-emitting device. The semiconductor light-emitting device includes a substrate, a Negative-type semiconductor, a quantum well, an electron-blocking layer, and a Positive-type semiconductor arranged in a sequential stack. The quantum well includes a first quantum well, a second quantum well, and a third quantum well, and there are differences among a dielectric constant, a refractive index, a forbidden bandwidth, and an electron effective mass of the first quantum well, a dielectric constant, a refractive index, a forbidden bandwidth, and an electron effective mass of the second quantum well, and a dielectric constant, a refractive index, a forbidden bandwidth, and an electron effective mass of the third quantum well to make dielectric constants, refractive indexes, forbidden bandwidths and the electron effective masses of the semiconductor light-emitting device distributed in a gradient in at least one direction. The quantum well includes a periodic structure consisting of a well layer and a barrier layer, the periodic structure having a count of periods of 1 to 50; a coefficient of thermal expansion of the well layer is smaller than or equal to a coefficient of thermal expansion of the barrier layer; an elastic coefficient of the well layer is smaller than or equal to an elastic coefficient of the barrier layer; a lattice constant of the well layer is greater than or equal to a lattice constant of the barrier layer; and a coefficient of spontaneous polarization of the well layer is smaller than or equal to a coefficient of spontaneous polarization of the barrier layer.

In some embodiments, a dielectric constant of the Negative-type semiconductor is a, a dielectric constant of the well layer of the first quantum well is b, a dielectric constant of the well layer of the second quantum well is c, a dielectric constant of the well layer of the third quantum well is d, and a dielectric constant of the electron-blocking layer is e, a dielectric constant of the Positive-type semiconductor is f, and a gradient relationship of the dielectric constants of the semiconductor light-emitting device is 12≥d≥c≥b≥f≥aże≥8.

In some embodiments, a refractive index of the Negative-type semiconductor is g, a refractive index of the well layer of the first quantum well is h, a refractive index of the well layer of the second quantum well is i, a refractive index of the well layer of the third quantum well is j, a refractive index of the electron-blocking layer is k, a refractive index of the Positive-type semiconductor is l, and a gradient relationship of the refractive indexes of the semiconductor light-emitting device is 3.5≥j≥i≥h≥l≥g≥k≥1.5.

In some embodiments, a forbidden bandwidth of the Negative-type semiconductor is u, a forbidden bandwidth of the well layer of the first quantum well is v, a forbidden bandwidth of the well layer of the second quantum well is w, a forbidden bandwidth of the well layer of the third quantum well is x, a forbidden bandwidth of the electron-blocking layer is y, a forbidden bandwidth of the Positive-type semiconductor is z, and a gradient relationship of the forbidden bandwidths of the semiconductor light-emitting device is 6.5 eV≥y≥u≥z≥v≥w≥x≥0.5 eV.

In some embodiments, an electron effective mass of the Negative-type semiconductor is o, an electron effective mass of the well layer of the first quantum well is p, an electron effective mass of the well layer of the second quantum well is q, and an electron effective mass of the well layer of the third quantum well is r, an electron effective mass of the electron-blocking layer is s, an electron effective mass of the Positive-type semiconductor is t, and a gradient relationship of the electron effective masses of the semiconductor light-emitting device is 10 mₑ≥s≥0≥t≥p≥q≥r≥0.01 mₑ.

In some embodiments, an element concentration distribution of the electron-blocking layer includes a Mg doping concentration distribution, an Al element concentration distribution, an In element concentration distribution, a Si doping concentration distribution, a C element concentration distribution, a H element concentration distribution and an O element concentration distribution in at least one direction; the Mg doping concentration distribution of the electron-blocking layer is parabolic, a peak position of the Mg doping concentration distribution shows a descending trend in a direction of an interface of the quantum well, a descending angle of the Mg doping concentration distribution is q, and an angle range of the φ is 30°≤φ≤90°; the Si doping concentration distribution of the electron-blocking layer is W-shaped, the Si doping concentration distribution shows a descending trend in a direction of the quantum well, a descending angle of the Si doping concentration distribution is θ, and an angle range of the θ is 20°≤θ≤85°; the Al element concentration distribution of the electron-blocking layer is M-shaped, a peak position of the Al element concentration distribution shows a descending trend in the direction of the quantum well, a descending angle of the Al element concentration distribution is a, and an angle range of the α is 10°≤α≤80°; the In element concentration distribution of the electron-blocking layer is parabolic, a peak position of the In element concentration distribution shows a descending trend in the direction of the quantum well, a descending angle of the In element concentration distribution is p, and an angle range of the ρ is 15°≤ρ≤85°; a peak position of the H element concentration distribution of the electron-blocking layer shows a descending trend in the direction of the quantum well, a descending angle of the H element concentration distribution is ε, and an angle range of the ε is 15°≤ε≤85°; a peak position of the C element concentration distribution of the electron-blocking layer shows a descending trend in the direction of the quantum well, a descending angle of the C element concentration distribution is δ, and an angle range of the δ is 10°≤δ≤80°; and a peak position of the O element concentration distribution of the electron-blocking layer shows a descending trend in the direction of the quantum well, a descending angle of the O element concentration distribution is Ψ, and an angle range of the Ψ is 25°≤Ψ≤85°.

In some embodiments, a relationship of the descending angles of the electron-blocking layer is 10°≤α≤δ≤ρ≤ε≤θ≤Ψ≤φ≤85°.

In some embodiments, an electron effective mass distribution of the electron-blocking layer is V-shaped or M-shaped; a piezoelectric polarization coefficient distribution of the electron-blocking layer is M-shaped; a dielectric constant distribution of the electron-blocking layer is inverted V-shaped; an Al/O element concentration ratio distribution of the electron-blocking layer is M-shaped and an In/O element concentration ratio distribution of the electron-blocking layer is N-shaped; and a Mg/O element concentration ratio distribution of the electron-blocking layer is parabolic.

In some embodiments, the well layer of the first quantum well includes at least one of InGaN, GaN, AlGaN, AlInGaN, or AlInN, and a depth of the well layer of the first quantum well is 5 Å˜80 Å; the barrier layer of the first quantum well includes at least one of InGaN, GaN, AlGaN, AlInGaN GaN, AlGaN, AlInGaN, or AlN, and a depth of the barrier layer of the first quantum well is 10 Å-500 Å; an Al element concentration distribution of the first quantum well shows a descending trend in a direction of the Negative-type semiconductor, a descending angle of the Al element concentration distribution is v, and an angle range of the v is 15°≤v≤75°; and a C/O element concentration ratio distribution of the first quantum well is V-shaped, the C/O element concentration ratio distribution shows a descending trend in a direction of the Positive-type semiconductor, a descending angle of the C/O element concentration ratio distribution is w, and an angle range of the ω is 20°≤ω≤80°; he well layer of the second quantum well includes at least one of InGaN, GaN, AlGaN, AlInGaN, or AlInN, and a depth of the well layer of the second quantum well is 5 Å˜100 Å; the barrier layer of the second quantum well includes at least one of InGaN, GaN, AlGaN, AlInGaN, GaN, AlGaN, AlInN, or AlN, and a depth of the barrier layer of the second quantum well is 10 Å˜300 Å; an Al element concentration distribution of the second quantum well shows a descending trend in the direction of the Negative-type semiconductor, a descending angle of the Al element concentration distribution is μ, and an angle range of the μ is 20°≤μ≤80°; and a C/O element concentration ratio distribution of the second quantum well is L-shaped, the C/O element concentration ratio distribution shows a descending trend in the direction of the Positive-type semiconductor, a descending angle of the C/O element concentration ratio distribution is y, and an angle range of the γ is 25°≤γ≤85°; the well layer of the third quantum well includes at least one of InGaN, GaN, AlGaN, AlInGaN, or AlInN, and a depth of the well layer of the third quantum well is 5 Å˜150 Å; the barrier layer of the third quantum well includes at least one of InGaN, GaN, AlGaN, AlInGaN GaN, AlGaN, AlInGaN, AlInN, or AlN, and a depth of the barrier layer of the third quantum well is 10 Å˜200 Å; an Al element concentration distribution of the third quantum well shows a descending trend in the direction of the Negative-type semiconductor, a descending angle of the Al element concentration distribution is λ, and an angle range of the λ is 30≤λ≤90°; a C/O element concentration ratio distribution of the third quantum well shows a descending trend in the direction of the Negative-type semiconductor, a descending angle of the C/O element concentration ratio distribution is β, and an angle range of the β is 10°≤β≤70°; a H/O element concentration ratio distribution of the third quantum well shows a descending trend in the direction of the Negative-type semiconductor, an descending angle of the H/O element concentration ratio distribution is K, and an angle range of the K is 20°≤K≤80°; and a relationship of the descending angles of the Al/O element concentration distribution of the first quantum well, the second quantum well, and the third quantum well, the descending angles of the C/O element concentration ratio distribution of the first quantum well, the second quantum well, and the third quantum well, and the descending angle of the H/O element concentration ratio distribution of the third quantum well is 10°≤β≤v≤μ≤ω≤K≤γ≤λ≤90°.

In some embodiments, the Negative-type semiconductor and the Positive-type semiconductor include at least one of AlGaN, GaN, InGaN, InN, AlInN, AlInGaN, AlN, GaAs, GaP, InP, AlGaAs, AlInGaAs, AlGaInP, InGaAs, InGaAsN, AlInAs, AlInP, AlGaP, InGaP, GaSb, InSb, InAs, InAsSb, AlGaSb, AlSb, InGaSb, AlGaAsSb, InGaAsSb, SiC, Ga₂O₃, or BN; a depth of the Negative-type semiconductor is 5 Å˜80,000 Å, and a depth of the Positive-type semiconductor is 5 Å˜9,000 Å; and the substrate includes at least one of sapphire, silicon, Ge, SiC, AlN, InAs, GaSb, GaN, GaAs, InP, a sapphire/SiO₂ composite substrate, a sapphire/AlN composite substrate, sapphire/SiNx, magnesium-aluminum spinel MgAl₂O₄, MgO, ZnO, ZrB₂, LiAlO₂, or a LiGaO₂ composite substrate.

### BRIEF DESCRIPTION OF THE DRAWINGS

The present disclosure is further illustrated in terms of exemplary embodiments. These exemplary embodiments are described in detail according to the drawings. These embodiments are non-limiting exemplary embodiments, in which like reference numerals represent similar structures, wherein:

FIG. 1 is a schematic diagram of a structure of a semiconductor light-emitting device according to some embodiments of the present disclosure;

FIG. 2 is a diagram of a secondary ion mass spectroscopy (SIMS) of a structure of a semiconductor light-emitting device according to some embodiments of the present disclosure;

FIG. 3 is a diagram of a secondary ion mass spectrometry (SIMS) of a local structure of a quantum well of a semiconductor light-emitting device according to some embodiments of the present disclosure;

FIG. 4 is a secondary ion mass spectrometry (SIMS) of a local structure of an electron-blocking layer of a semiconductor light-emitting device according to some embodiments of the present disclosure;

FIG. 5 is a transmission electron microscope (TEM) image of a first quantum well of a semiconductor light-emitting device according to some embodiments of the present disclosure;

FIG. 6 is a transmission electron microscope (TEM) image of a second quantum well of a semiconductor light-emitting device according to some embodiments of the present disclosure;

FIG. 7 is a transmission electron microscope (TEM) image of a third quantum well of a semiconductor light-emitting device according to some embodiments of the present disclosure;

FIG. 8 is a transmission electron microscope (TEM) image of an electron-blocking layer of a semiconductor light-emitting device according to some embodiments of the present disclosure; and

In the figures, 100: substrate, 101: Negative-type semiconductor, 102: quantum well, 102a: first quantum well, 102b: second quantum well, 102c: third quantum well, 103: electron-blocking layer, 104: Positive-type semiconductor.

### DETAILED DESCRIPTION

In order to more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that the “system,” “device,” “unit,” and/or “module” used herein are one method to distinguish different components, elements, parts, sections, or assemblies of different levels. However, if other words can achieve the same purpose, the words can be replaced by other expressions.

As used in the disclosure and the appended claims, the singular forms “a,” “an,” and “the” include plural referents unless the content clearly dictates otherwise; the plural forms may be intended to include singular forms as well. In general, the terms “comprise,” “comprises,” and/or “comprising,” “include,” “includes,” and/or “including,” merely prompt to include steps and elements that have been clearly identified, and these steps and elements do not constitute an exclusive listing. The methods or devices may also include other steps or elements.

The flowcharts used in the present disclosure illustrate operations that the system implements according to the embodiment of the present disclosure. It should be understood that the foregoing or following operations may not necessarily be performed exactly in order. Instead, the operations may be processed in reverse order or simultaneously. Besides, one or more other operations may be added to these processes, or one or more operations may be removed from these processes.

In order to emit visible light, the light is emitted using a semiconductor light-emitting device in the prior art. The proposed semiconductor light-emitting device may include a Negative-type semiconductor, a quantum well, an electron-blocking layer, and a Positive-type semiconductor. The semiconductor light-emitting device may control the Negative-type semiconductor and the Positive-type semiconductor under the action of an external electric field to provide electrons and holes and recombine the electrons and holes in the quantum well. Through the recombination of the electrons and the holes, photons are generated and visible light is emitted. However, a hole ionization efficiency of the semiconductor light-emitting device is much lower than an electron ionization efficiency of the semiconductor light-emitting device, resulting in too few holes and too many electrons injected into multiple quantum wells and low luminescence efficiency of the multiple quantum wells.

The present disclosure describes a semiconductor light-emitting device. Dielectric constants, refractive indexes, forbidden bandwidths, and electron effective masses of the semiconductor light-emitting device may be designed to be distributed in a dielectric constant gradient, a refractive index gradient, a forbidden bandwidth gradient, and an electron effective mass gradient in at least one direction, which improves reflection and refraction of light, increases a light-emitting angle of outgoing light (e.g., the light-emitting angle may be at least increased from 80° ˜120° to) 120° ˜200°, changes a light outgoing path, and improves the light extraction efficiency (e.g., the light extraction efficiency may be at least increased from 40%˜60% to 60%˜95%).

It should be understood that scenarios of the semiconductor light-emitting device of the present disclosure are only some examples or embodiments of the present disclosure. For those skilled in the art, the present disclosure may be applied to other similar scenarios according to these accompanying drawings without creative labor.

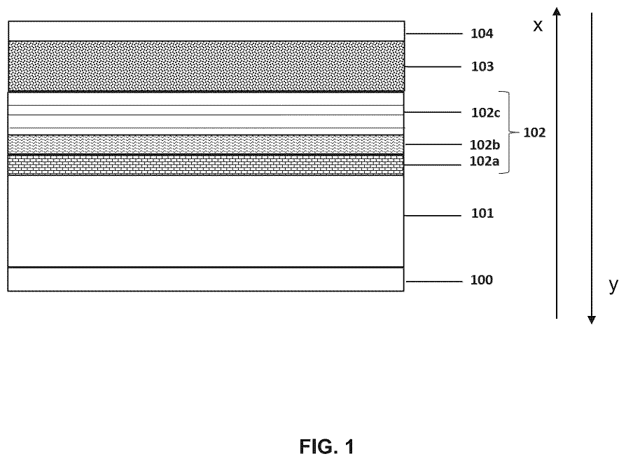

The semiconductor light-emitting device involved in some embodiments of the present disclosure is described in detail below in connection with FIGS. 1-8. It should be noted that the following embodiments are used only to explain the present disclosure and do not constitute a limitation of the present disclosure.

FIG. 1 is a schematic diagram of a structure of a semiconductor light-emitting device according to some embodiments of the present disclosure. In some embodiments, as shown in FIG. 1, the semiconductor light-emitting device may include a substrate 100, a Negative-type semiconductor 101, a quantum well 102, an electron-blocking layer 103, and a Positive-type semiconductor 104. The substrate 100, the Negative-type semiconductor 101, the quantum well 102, the electron-blocking layer 103, and the Positive-type semiconductor 104 may be arranged in a sequential stack.

The substrate 100 refers to a component used to bear other components (e.g., the Negative-type semiconductor 101 or the quantum well 102) in the semiconductor light-emitting device 100.

In some embodiments, the substrate 100 may be made of a material that satisfies a preset substrate condition. The preset substrate condition may include that a lattice mismatch and a thermal mismatch of the material of the substrate 100 is smaller than or equal to a preset mismatch threshold. The preset mismatch threshold may be determined based on human experience and material data of historical semiconductors. That is, the substrate 100 may be made of the material with a relatively small lattice mismatch and a relatively less thermal mismatch to reduce a defect density and a polarization effect of the semiconductor light-emitting device 100. For more descriptions regarding the lattice mismatch and the thermal mismatch, please refer to the relevant descriptions in the present disclosure below.

In some embodiments, the substrate 100 may include sapphire, silicon, Ge, SiC, AlN, InAs, GaSb, GaN, GaAs, InP, a sapphire/SiO₂ composite substrate, a sapphire/AlN composite substrate, sapphire/SiNx, magnesium-aluminum spinel MgAl₂O₄, MgO, ZnO, ZrB₂, LiAlO₂, a LiGaO₂ composite substrate, or the like, or any combination thereof.

The Negative-type semiconductor 101 (N-type semiconductor), also known as an electronic semiconductor, refers to an impurity semiconductor in which a concentration of free electrons is greater than a concentration of holes. The free electrons are mainly provided by impurity atoms in the Negative-type semiconductor 101, and the holes may be formed by thermal excitation. In some embodiments, a concentration of impurities doped into the Negative-type semiconductor 101 may be positively correlated with conductivity of the free electrons. For example, the more impurities that are doped into the Negative-type semiconductor 101, the higher the concentration of the free electrons, and the stronger the conductivity of the free electrons.

In some embodiments, the Negative-type semiconductor 101 may be stacked on an upper part of the substrate 100. In some embodiments, the Negative-type semiconductor 101 may provide the electrons under the action of an external electric field so that the electrons are subsequently recombined with the holes. Exemplarily, as shown in FIG. 1, the electrons generated by the Negative-type semiconductor 101 may move in a first direction (direction x as shown in FIG. 1) to the quantum well to be recombined with the holes. For more descriptions regarding the quantum well and the holes, see the related descriptions below.

The quantum well 102 refers to a region that exhibits a two-dimensional characteristic through electron motion. In some embodiments, the quantum well 102 may be disposed between the Negative-type semiconductor 101 and the Positive-type semiconductor 104, so that the electrons and the holes may be assembled for light emitting.

In some embodiments, the quantum well 102 may include a periodic structure consisting of a well layer and a barrier layer. The periodic structure has a count of periods of 1 to 50. The quantum well 102 may be set up periodically by alternating well layers and barrier layers, and under the action of an applied electric field, the electrons in the quantum well 102 transition from a low energy band material (e.g., the barrier layer) to a high energy band material (e.g., the well layer) and release energy. The energy is converted into photons, thereby generating a laser.

In some embodiments, there may be a difference between a parameter of the well layer and a parameter of the barrier layer. For example, the parameter may include a coefficient of thermal expansion, an elastic coefficient, a lattice constant, a coefficient of spontaneous polarization etc. The parameter difference between the well layer and the barrier layer may make at least a portion of the structure (e.g., the well layer or the barrier layer) in the quantum well 102 to be matched with the substrate 100, thereby reducing a possibility of the lattice mismatch and the thermal mismatch of the semiconductor light-emitting device. The lattice mismatch refers to a phenomenon in which a distance and an angle between atoms in a crystal do not meet a requirement of an ideal crystal. The thermal mismatch refers to a mismatch phenomenon caused by different coefficients of thermal expansion of the material when the temperature changes.

In some embodiments, a coefficient of thermal expansion of the well layer may be smaller than or equal to a coefficient of thermal expansion of the barrier layer; an elastic coefficient of the well layer may be smaller than or equal to an elastic coefficient of the barrier layer; a lattice constant of the well layer may be greater than or equal to a lattice constant of the barrier layer; and a coefficient of spontaneous polarization of the well layer may be smaller than or equal to a coefficient of spontaneous polarization of the barrier layer.

In some embodiments of the present disclosure, the differences between the coefficient of thermal expansion, the elastic coefficient, the lattice constant, and the coefficient of spontaneous polarization of the well layer and the coefficient of thermal expansion, the elastic coefficient, the lattice constant, and the coefficient of spontaneous polarization of the barrier layer of the quantum well may be designed, which reduces the thermal mismatch and lattice mismatch of the quantum well, reduces a quantum confinement stark effect and a polarization effect of the quantum well, enhances a quantum confinement effect, reduces the electron overflow and the valance band offset, enhances the crystal quality and the interface quality of the quantum well, enhances an overlapping possibility of an electron-hole wave function of the quantum well, enhances a hot state (e.g., in an environment of 125° C.) and cold state (e.g., in an environment of 25° C.) efficiency ratio of the semiconductor light-emitting device (e.g., enhances the hot state and cold state efficiency ratio from 40%˜80% to 80%˜95%), inhibits the deterioration of the crystal quality of the interface quality in the aging process, reduces a possibility of carriers being trapped by defects in the aging process, and reduces the change of aging resistance to make an aging voltage attenuation range decrease from +/−0.05V˜0.1V to +/−0.01˜0.05V.

In some embodiments, the quantum well 102 may further include a first quantum well 102a, a second quantum well 102b, and a third quantum well 102c.

In some embodiments, the first quantum well 102a, the second quantum well 102b, and the third quantum well 102c may be disposed in a sequential stack. As shown in FIG. 1, the first quantum well 102a may be affixed to the Negative-type semiconductor 101, the third quantum well 102c may be affixed to the electron-blocking layer 103, and the second quantum well 102b may be disposed between the first quantum well 102a and the third quantum well 102c.

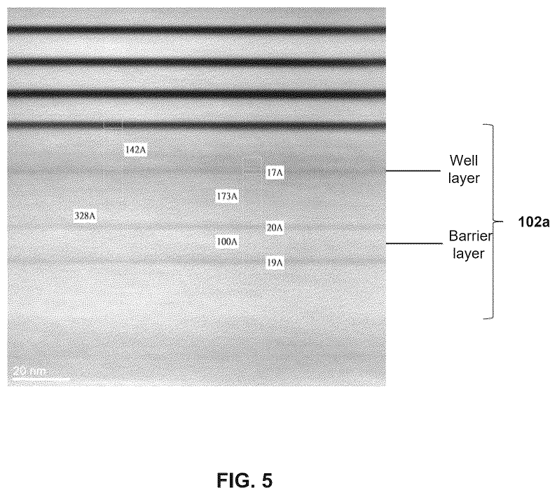

In some embodiments, structures of the first quantum well 102a, the second quantum well 102b, and the third quantum well 102c may be similar, and each quantum well may include at least one periodic structure consisting of the well layer and the barrier layer. For more descriptions regarding the well layer and the barrier layer of the first quantum well 102a, the well layer and the barrier layer of the second quantum well 102b, and the well layer and the barrier layer of the third quantum well 102c, see FIG. 5-8 below and their related descriptions.

In some embodiments, there is a difference among an optical parameter of the first quantum well 102a, an optical parameter of the second quantum well 102b, and an optical parameter of the third quantum well 102c to make the optical parameters of the semiconductor light-emitting device distributed in a gradient in at least one direction. The optical parameter may include a dielectric constant, a refractive index, a forbidden bandwidth, an electron effective mass, or the like, or any combination thereof.

The dielectric constant refers to a main parameter that reflects a dielectric property or a polarization property of the quantum well 102 under the action of an electrostatic field. The refractive index refers to a change in a speed of light as it travels through the quantum well compared to a speed it travels in a vacuum. The forbidden bandwidth refers to a width of a band gap between an energy band where the free electrons are located and an energy band where the holes are located. The electron effective mass refers to an equivalent mass that reflects an external force on the electrons and a traction force of internal particles.

In some embodiments, the at least one direction may include a horizontal direction and/or a depth direction of the semiconductor light-emitting device. The horizontal direction of the semiconductor light-emitting device refers to any direction parallel to projection of a horizontal plane of the semiconductor light-emitting device. The depth direction of the semiconductor light-emitting device refers to a direction perpendicular to the projection of the horizontal plane of the semiconductor light-emitting device, for example, the direction x or the direction y shown in FIG. 1.

The gradient distribution refers to a phased distribution or a gradual distribution of the optical parameter in one or more directions, for example, monotonically decreasing or increasing, normal distribution, etc. For example, in some embodiments, the gradient distribution of the optical parameter may include the dielectric constant monotonically increasing or decreasing from the first quantum well 102a to the third quantum well 102c, etc.

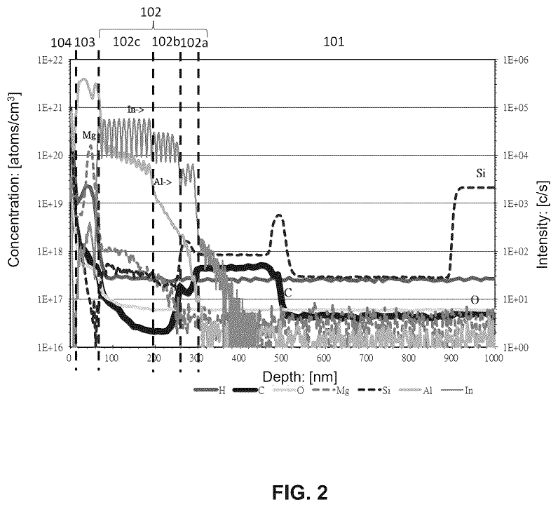

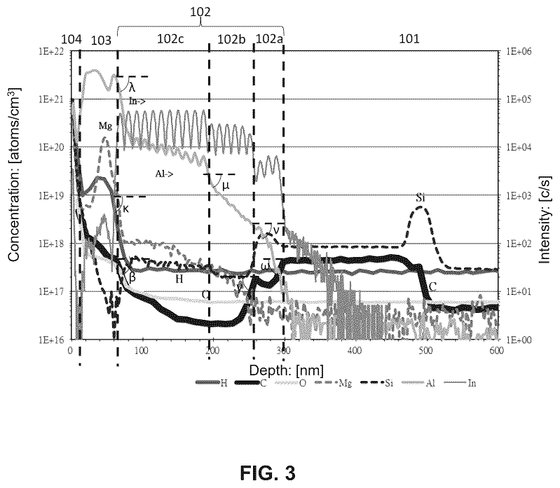

In some embodiments, the optical parameters of other components (e.g., the Negative-type semiconductor 101, the electron-blocking layer 103, and the Positive-type semiconductor 104) of the semiconductor light-emitting device may also be different, so that an overall optical parameter of the semiconductor light-emitting device is distributed in a gradient in the at least one direction. For more descriptions regarding the gradient distribution, see FIGS. 2-3 below and their related descriptions.

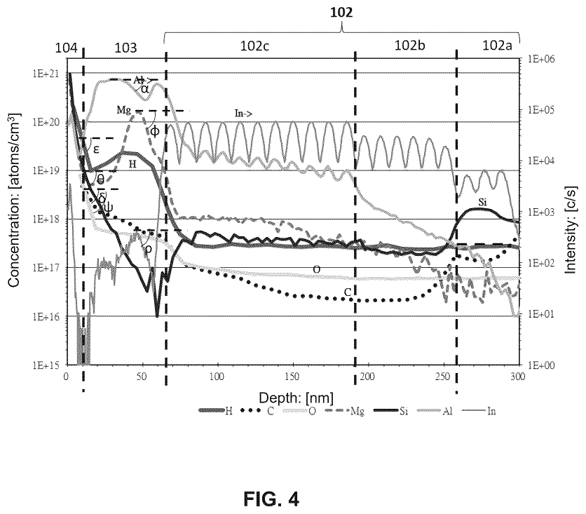

The electron-blocking layer 103 refers to a region that blocks entry of the free electrons. In some embodiments, a material of the electron-blocking layer 103 may include a dielectric material such as aluminum nitride, aluminum gallium nitride, gallium nitride, or the like, or any combination thereof. In some embodiments, the electron-blocking layer 103 may be disposed between the quantum well 102 and the Positive-type semiconductor 104 to prevent the electrons moving in the quantum well 102 from entering the Positive-type semiconductor 104. For more descriptions regarding the electron-blocking layer 103, see FIG. 4 below and its related descriptions.

The Positive-type semiconductor 104, also known as a P-type semiconductor, refers to an impurity semiconductor in which the concentration of holes is greater than the concentration of free electrons. The holes are mainly provided by impurity atoms in the Positive-type semiconductor 104, and the free electrons may be formed by thermal excitation. In some embodiments, a concentration of impurities doped into the Positive-type semiconductor 104 may be positively correlated with the concentration of holes. For example, the more impurities that are doped into the Positive-type semiconductor 104, the higher the concentration of holes.

In some embodiments, the Positive-type semiconductor 104 may be stacked on an upper part of the electron-blocking layer. In some embodiments, the Positive-type semiconductor 104 may provide the holes under the action of the external electric field so that the free electrons are subsequently recombined with the holes. Exemplarily, as shown in FIG. 1, the holes generated by the Positive-type semiconductor 104 may move in a second direction (direction y as shown in FIG. 1) to the quantum well to be recombined with the free electrons. For more descriptions regarding the quantum well and the holes, see the related descriptions below.

In some embodiments, a material of the Negative-type semiconductor 101 and a material of the Positive-type semiconductor 104 may be the same or different. In some embodiments, the material of the Negative-type semiconductor 101 and the material of the Positive-type semiconductor 104 may include AlGaN, GaN, InGaN, InN, AlInN, AlInGaN, AlN, GaAs, GaP, InP, AlGaAs, AlInGaAs, AlGaInP, InGaAs, InGaAsN, AlInAs, AlInP, AlGaP, InGaP, GaSb, InSb, InAs, InAsSb, AlGaSb, AlSb, InGaSb, AlGaAsSb, InGaAsSb, SiC, Ga₂O₃, BN, or the like, or any combination thereof.

In some embodiments, a depth of the Negative-type semiconductor 101 may be within a first preset depth range. In some embodiments, the depth of the Positive-type semiconductor 104 may be within a second preset depth range. The first preset depth range and the second preset depth range may be determined in various ways, such as based on human experience or historical semiconductor data. In some embodiments, the depth of the Negative-type semiconductor 101 may be 5 Å˜80,000 Å, and the depth of the Positive-type semiconductor 104 may be 5 Å˜9,000 Å. For example, the depth of the Negative-type semiconductor 101 may be 5 Å, 100 Å, 5,000 Å, or 80,000 Å, and the depth of the Positive-type semiconductor 104 may be 5 Å, 300 Å, 6,500 Å, or 9,000 Å.

In some embodiments of the present disclosure, the dielectric constant, the refractive index, the forbidden bandwidth, and the electron effective mass of the quantum well may be designed to be distributed in a gradient in the at least one direction, which improves the reflection and refraction of light, increases a light-emitting angle of outgoing light, changes a light outgoing path, and improves the light extraction efficiency.

Moreover, the differences between the coefficient of thermal expansion, the elastic coefficient, the lattice constant, and the coefficient of spontaneous polarization of the well layer and the coefficient of thermal expansion, the elastic coefficient, the lattice constant, and the coefficient of spontaneous polarization of the barrier layer of the quantum well may be by designed, which reduces the thermal mismatch and lattice mismatch of the quantum well, reduces the quantum confinement stark effect and the polarization effect of the quantum well, enhances the quantum confinement effect, reduces the electron overflow and the valance band offset, enhances the crystal quality and the interface quality of the quantum well, enhances the overlapping possibility of the electron-hole wave function of the quantum well, enhances the hot state and cold state efficiency ratio of semiconductor light-emitting device, inhibits the deterioration of the crystal quality and the interface quality in the aging process, reduces a possibility of carriers being trapped by defects in the aging process, and reduces the change of aging resistance.

FIG. 2 is a diagram of a secondary ion mass spectroscopy (SIMS) of a structure of a semiconductor light-emitting device according to some embodiments of the present disclosure. FIG. 3 is a diagram of a secondary ion mass spectrometry (SIMS) of a local structure of a quantum well of a semiconductor light-emitting device according to some embodiments of the present disclosure. As shown in FIGS. 2 and 3, the abscissa may represent a depth of the semiconductor light-emitting device, and the ordinate may represent a concentration of an element of the semiconductor light-emitting device.

In some embodiments, dielectric constants of the semiconductor light-emitting device may be distributed in a gradient in a preset dielectric range. The preset dielectric range may be set based on human experience or historical data. For example, the preset dielectric range may include [8, 12]. In some embodiments, a dielectric constant of the Negative-type semiconductor 101 is a, a dielectric constant of a well layer of the first quantum well 102a is b, a dielectric constant of a well layer of the second quantum well 102b is c, a dielectric constant of a well layer of the third quantum well 102c is d, and a dielectric constant of the electron-blocking layer 103 is e, a dielectric constant of the Positive-type semiconductor 104 is f, and a gradient relationship of the dielectric constants of the semiconductor light-emitting device is 12≥d≥c≥b≥f≥a≥e≥8.

Exemplarily, the dielectric constant of the Negative-type semiconductor 101 is 9, the dielectric constant of the well layer of the first quantum well 102a is 10.9, the dielectric constant of the well layer of the second quantum well 102b is 11.5, the dielectric constant of the well layer of the third quantum well 102c is 12, and the dielectric constant of the electron-blocking layer 103 is 8, the dielectric constant of the Positive-type semiconductor 104 is 10.2, and the gradient relationship of the dielectric constants of the semiconductor light-emitting device is 12≥d≥c≥b≥f≥a≥e≥8.

In some embodiments of the present disclosure, the dielectric constants are designed to be distributed in a gradient in at least one direction and the gradient distribution of the dielectric constant is adjusted, which controls the reflection and refraction of light output by the semiconductor light-emitting device, controls the light-emitting angle of the outgoing light, and improves the light extraction efficiency of the semiconductor light-emitting device.

In some embodiments, refractive indexes of the semiconductor light-emitting device may be distributed in a gradient in a preset refraction range. The preset refraction range may be set based on human experience or historical data. For example, the preset refraction range may include [1.5, 3.5]. In some embodiments, a refractive index of the Negative-type semiconductor 101 is g, a refractive index of the well layer of the first quantum well 102a is h, a refractive index of the well layer of the second quantum well 102b is i, a refractive index of the well layer of the third quantum well 102c is j, a refractive index of the electron-blocking layer 103 is k, a refractive index of the Positive-type semiconductor 104 is l, and a gradient relationship of the refractive indexes of the semiconductor light-emitting device is 3.5≥j≥i≥h≥l≥g≥k≥1.5.

Exemplarily, the refractive index of the Negative-type semiconductor 101 is g, the refractive index of the well layer of the first quantum well 102a is h, a refractive index of the well layer of the second quantum well 102b is i, the refractive index of the well layer of the third quantum well 102c is j, the refractive index of the electron-blocking layer 103 is k, the refractive index of the Positive-type semiconductor 104 is l, and the gradient relationship of the refractive indexes of the semiconductor light-emitting device is 3.5≥j≥i≥h≥1≥g≥k≥1.5.

In the embodiments of the present disclosure, the refractive indexes are designed to be distributed in a gradient in at least one direction, which enhances the reflection and refraction of light, increases the light-emitting angle of the outgoing light, and improves the light extraction efficiency of the semiconductor light-emitting device.

In some embodiments, forbidden bandwidths of the semiconductor light-emitting device may be distributed in a gradient in a preset forbidden band range. The preset forbidden band range may be set based on human experience or historical data. For example, the preset refraction range may include [0.5 eV, 6.5 eV]. In some embodiments, a forbidden bandwidth of the Negative-type semiconductor 101 is u, a forbidden bandwidth of the well layer of the first quantum well 102a is v, a forbidden bandwidth of the well layer of the second quantum well 102b is w, a forbidden bandwidth of the well layer of the third quantum well 102c is x, a forbidden bandwidth of the electron-blocking layer 103 is y, a forbidden bandwidth of the Positive-type semiconductor 104 is z, and a gradient relationship of the forbidden bandwidths of the semiconductor light-emitting device is 6.5 eV≥y≥u≥z≥v≥w≥x≥0.5 eV.

Exemplarily, the forbidden bandwidth of the Negative-type semiconductor 101 is 5.5 eV, the forbidden bandwidth of the well layer of the first quantum well 102a is 3 eV, the forbidden bandwidth of the well layer of the second quantum well 102b is 2.1 eV, the forbidden bandwidth of the well layer of the third quantum well 102c is 0.5 eV, the forbidden bandwidth of the electron-blocking layer 103 is 6.5 eV, and the forbidden bandwidth of the Positive-type semiconductor 104 is 4.5 eV.

In some embodiments of the present disclosure, the forbidden bandwidths are designed to be distributed in a gradient in at least one direction, which improves the overlapping possibility and an overlapping position of the electron-hole wave function, changes the light outgoing path, and improves the light extraction efficiency.

In some embodiments, electron effective masses of the semiconductor light-emitting device may be distributed in a gradient in a preset mass range. The preset mass range may be set based on human experience or historical data. For example, the preset mass range may include [1.5, 3.5]. In some embodiments, an electron effective mass of the Negative-type semiconductor 101 is o, an electron effective mass of the well layer of the first quantum well 102a is p, an electron effective mass of the well layer of the second quantum well 102b is q, and an electron effective mass of the well layer of the third quantum well 102c is r, an electron effective mass of the electron-blocking layer 103 is s, an electron effective mass of the Positive-type semiconductor 104 is t, and a gradient relationship of the electron effective masses of the semiconductor light-emitting device is 10 mₑ≥s≥0≥t≥p≥q≥r≥0.01 mₑ.

Exemplarily, the electron effective mass of the Negative-type semiconductor 101 is 7 mₑ, the electron effective mass of the well layer of the first quantum well 102a is 5.5 mₑ, the electron effective mass of the well layer of the second quantum well 102b is 3 mₑ, and the electron effective mass of the well layer of the third quantum well 102c is 0.01 mₑ, the electron effective mass of the electron-blocking layer 103 is 10 mₑ, and the electron effective mass of the Positive-type semiconductor 104 is 7 mₑ.

In the embodiments of the present disclosure, the dielectric constants and the refractive indexes are designed to be distributed in a gradient in at least one direction, which improves the reflection and refraction of light, increases the light-emitting angle of the outgoing light (e.g., the light-emitting angle may be at least increased from 80°˜ 120° to 120° ˜200°. The forbidden bandwidths and the electron effective masses are designed to be distributed in a gradient in at least one direction, which improves the overlapping possibility and the overlapping position of the electron-hole wave function, changes the light outgoing path, improves the light extraction efficiency (e.g., the light extraction efficiency may be at least improved from 40%˜60% to 60%˜95%).

FIG. 2 is a diagram of a secondary ion mass spectroscopy (SIMS) of a structure of a semiconductor light-emitting device according to some embodiments of the present disclosure. FIG. 3 is a diagram of a secondary ion mass spectrometry (SIMS) of a local structure of a quantum well of a semiconductor light-emitting device according to some embodiments of the present disclosure. As shown in FIGS. 2 and 3, the abscissa may represent a depth of the semiconductor light-emitting device, and the ordinate may represent a concentration of an element of the semiconductor light-emitting device. Accordingly, the broken line in FIGS. 2-3 may represent an element concentration of an element corresponding to the broken line at a certain depth in the semiconductor light-emitting device, the broken line may represent a concentration distribution condition of the element corresponding to the broken line in the semiconductor light-emitting device. For example, the broken lines corresponding to the In element in the first quantum well 102a, the second quantum well 102b, and the third quantum well 102c are distributed in a wave-like distribution. That is, In element concentrations in the first quantum well 102a, the second quantum well 102b, and the third quantum well 102c are distributed in a wave-like distribution.

In some embodiments, the electron-blocking layer may also be doped with a plurality of elements. The plurality of elements may exhibit different concentration distribution conditions in at least one direction. The plurality of elements may include a Mg doping element, an Al element, an In element, a Si doping element, a C element, a H element, an O element, or the like, or any combination thereof. In some embodiments, the at least one direction may include a direction toward the quantum well, a direction toward an interface of the quantum well, etc. In some embodiments, the concentration distribution condition may include one or more distribution states such as a parabolic distribution, an M-shaped distribution, a gradient descent distribution.

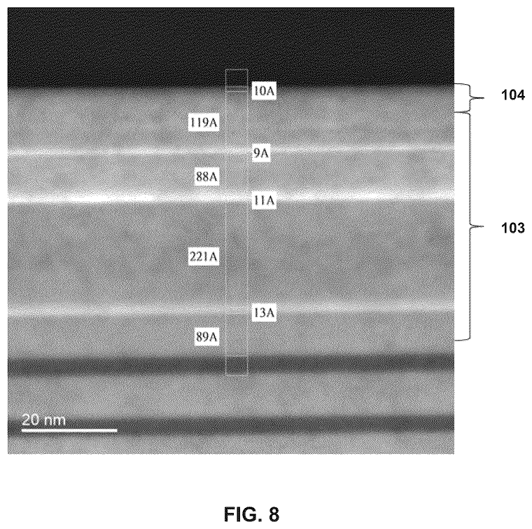

FIG. 4 is a secondary ion mass spectrometry (SIMS) of a local structure of an electron-blocking layer of a semiconductor light-emitting device according to some embodiments of the present disclosure. FIG. 8 is a transmission electron microscope (TEM) image of an electron-blocking layer of a semiconductor light-emitting device according to some embodiments of the present disclosure. In some embodiments, as shown in FIGS. 4 and 8, an element concentration distribution of the electron-blocking layer includes a Mg doping concentration distribution, an Al element concentration distribution, an In element concentration distribution, a Si doping concentration distribution, a C element concentration distribution, a H element concentration distribution and an O element concentration distribution in at least one direction.

In some embodiments, as shown in FIG. 4, the Mg doping concentration distribution of the electron-blocking layer 103 is parabolic, a peak position of the Mg doping concentration distribution shows a descending trend in a direction of an interface of the quantum well, a descending angle of the Mg doping concentration distribution is φ, and an angle range of the φ is 30°≤φ≤90°. The direction of the interface of the quantum well 102 refers to a direction from the electron-blocking layer 103, to an interface between the electron-blocking layer 103 and the quantum well 102.

The descending angle refers to a degree of change of an element descending distribution in the electron-blocking layer 103. In some embodiments, the descending angle φ of the Mg dopant concentration distribution may reflect a state of change of the descending distribution of the Mg doping concentration distribution from the electron-blocking layer 103 to the quantum well 102. In some embodiments, the descending angle φ of the Mg doping concentration distribution may be in a preset Mg angle range. The preset Mg angle range may be determined based on human experience or historical data. In some embodiments, the descending angle φ of the Mg doping concentration distribution may be in a range of 30°≤φ≤90°. Exemplary, the descending angle φ of the Mg doping concentration distribution may be 30°, 45°, 60°, or 90°.

In some embodiments, as shown in FIG. 4, the Si doping concentration distribution of the electron-blocking layer 103 may be W-shaped, the Si doping concentration distribution shows a descending trend in a direction of the quantum well, and a descending angle of the Si doping concentration distribution is θ, which is similar to the descending angle φ of the Mg doping concentration distribution. In some embodiments, the descending angle θ of the Si doping concentration distribution may be in a preset Si angle range. The preset Si angle range may be determined based on human experience or historical data. In some embodiments, the descending angle θ of the Si doping concentration distribution may be in an angle range of 20°≤θ≤85°. Exemplarily, the descending angle θ of the Si doping concentration distribution may be 20°, 45°, 60°, or 85°.

In some embodiments, as shown in FIG. 4, the Al element concentration distribution of the electron-blocking layer 103 is M-shaped, a peak position of the Al element concentration distribution shows a descending trend in the direction of the quantum well, and a descending angle of the Al element concentration distribution is α, which is similar to the descending angle φ of the Mg doping concentration distribution. In some embodiments, the descending angle α of the Al element concentration distribution may be in a preset Al angle range. The preset Al angle range may be determined based on human experience or historical data. In some embodiments, the descending angle α of the Al element concentration distribution may be in an angle range of 10°≤α≤80°. Exemplarily, the descending angle α of the Al element concentration distribution may be 10°, 45°, 70°, or 80°.

In some embodiments, as shown in FIG. 4, the In element concentration distribution of the electron-blocking layer 103 is parabolic, a peak position of the In element concentration distribution shows a descending trend in the direction of the quantum well, and a descending angle of the In element concentration distribution is ρ, which is similar to the descending angle φ of the Mg doping concentration distribution.

In some embodiments, the descending angle ρ of In element concentration distribution may be in a preset In angle range. The preset In angle range may be determined based on human experience or historical data. In some embodiments, the descending angle ρ of the In element concentration distribution may be in an angle range of 15°≤ρ≤85°. Exemplarily, the descending angle ρ of the In element concentration distribution may be 15°, 55°, 60°, or 85°.

In some embodiments, as shown in FIG. 4, a peak position of the H element concentration distribution of the electron-blocking layer 103 shows a descending trend in the direction of the quantum well, and a descending angle of the H element concentration distribution is ε, which is similar to the descending angle φ of the Mg doping concentration distribution. In some embodiments, the descending angle ε of the H element concentration distribution may be in a preset H-angle range. The preset H-angle range may be determined based on human experience or historical data. In some embodiments, the descending angle & of the H element concentration distribution may be in an angle range of 15°≤ε≤85°. Exemplarily, the descending angle ε of the H element concentration distribution may be 15°, 55°, 65°, or 85°.

In some embodiments, as shown in FIG. 4, a peak position of the C element concentration distribution of the electron-blocking layer 103 shows a descending trend in the direction of the quantum well 102, and a descending angle of the C element concentration distribution is δ. The descending angle δ of the C element concentration distribution is similar to the descending angle φ of the Mg doping concentration distribution. In some embodiments, the descending angle δ of the C element concentration distribution may be in a preset C angle range. The preset C angle range may be determined based on human experience or historical data. In some embodiments, the descending angle δ of the C element concentration distribution may be in an angle range of 10°≤δ≤80°. Exemplarily, the descending angle δ of the C element concentration distribution may be 10°, 55°, 65°, or 80°.

In some embodiments, as shown in FIG. 4, a peak position of the O element concentration distribution of the electron-blocking layer 103 shows a descending trend in the direction of the quantum well 102, and a descending angle of the O element concentration distribution is Ψ. The descending angle Ψ of the O element concentration distribution is similar to the descending angle φ of the Mg doping concentration distribution. In some embodiments, the descending angle Ψ of the O element concentration distribution may be in a preset O angle range. The preset O angle range may be determined based on human experience or historical data. In some embodiments, the descending angle Ψ of the O element concentration distribution may be in an angle range of 25°≤Ψ≤85. Exemplarily, the descending angle Ψ of the O element concentration distribution may be 25°, 45°, 55°, or 85°.

In the embodiments of the present disclosure, the Mg doping concentration distribution, Al element concentration distribution, In element concentration distribution, Si doping concentration distribution, C element concentration distribution, H element concentration distribution, and O element concentration distribution of the electron-blocking layer 103 are designed, which forms two-dimensional electron gas, three-dimensional electron gas, two-dimensional composite hole gas, or three-dimensional composite hole gas, enhances the efficiency of injecting the holes into the quantum well and the hole transport efficiency, reduces the efficiency droop of the semiconductor light-emitting device under high-current injection; enhances the lateral expansion and longitudinal expansion of electrons and holes, reduces the conductive resistance and series resistance, reduces the voltage of the semiconductor light-emitting device, and at the same time enhances the anti-Electro-Static discharge (ESD) capability.

In some embodiments, a descending angle of the electron-blocking layer 103 may also have different distribution relationships in a preset descending angle range. The descending angle range may be determined in various ways, such as based on human experience or historical data. In some embodiments, a relationship of the descending angle of the electron-blocking layer 103 is 10°≤α≤δ≤ρ≤ε≤θ≤Ψ≤φ≤85°.

Exemplarily, the descending angle φ of the Mg doping concentration distribution may be 85°, the descending angle θ of the Si doping concentration distribution may be 50°, the descending angle α of the Al element concentration distribution may be 10°, the descending angle ρ of the In element concentration distribution may be 35°, the descending angle ε of the H element concentration distribution may be 45°, the descending angle δ of the C element concentration distribution may be 20°, and the descending angle Ψ of the O element concentration distribution may be 60°.

In the embodiments of the present disclosure, the descending angle of the Mg doping concentration distribution, the descending angle of the Al element concentration distribution, the descending angle of the In element concentration distribution, the descending angle of the Si doping concentration distribution, the descending angle of the C element concentration distribution, the descending angle of the H element concentration distribution, and the descending angle of the O element concentration distribution of the electron-blocking layer 103 are designed, which enhances the efficiency of injecting the holes into the quantum-well and the hole transport efficiency, reduce the efficiency droop of the semiconductor light-emitting device under high-current injection, reduces the conductive resistance and series resistance, reduces the voltage of the semiconductor light-emitting device, and at the same time enhances the anti-ESD capability.

In some embodiments, an electron effective mass distribution, a piezoelectric polarization coefficient distribution, and a dielectric constant distribution of the electron-blocking layer 103 may also have different distribution relationships. The distribution relationship may be determined in various ways, such as based on human experience or historical data.

In some embodiments, as shown in FIG. 4, the electron effective mass distribution of the electron-blocking layer 103 is V-shaped or M-shaped; the piezoelectric polarization coefficient distribution of the electron-blocking layer 103 is M-shaped; the dielectric constant distribution of the electron-blocking layer 103 is inverted V-shaped; an Al/O element concentration ratio distribution of the electron-blocking layer 103 is M-shaped and an In/O element concentration ratio distribution of the electron-blocking layer 103 is N-shaped; and a Mg/O element concentration ratio distribution of the electron-blocking layer 103 is parabolic.

In some embodiments of the present disclosure, the descending angle of the Mg doping concentration distribution, the descending angle of the Si doping concentration distribution, the descending angle of the Al element concentration distribution, the descending angle of the In element concentration distribution, the descending angle of the H element concentration distribution, the descending angle of the C element concentration distribution, the descending angle of the O element concentration distribution, the M-shaped piezoelectric polarization coefficient distribution, the inverted V-shaped dielectric constant distribution, the M-shaped electron effective mass distribution of the electron-blocking layer 103 are designed, which forms the two-dimensional electron gas, the three-dimensional electron gas, the two-dimensional composite hole gas, or the three-dimensional composite hole gas, enhances the efficiency of injecting the holes into the quantum well and the hole transport efficiency, reduces the efficiency droop of the semiconductor light-emitting device under high-current injection (e.g., the efficiency droop is reduced from 40% to 70% to 5%˜35%), enhances the lateral expansion and longitudinal expansion of electrons and holes, reduces the conductive resistance and series resistance, reduces the voltage of the semiconductor light-emitting device (e.g., the voltage is reduced from 3.05 V to less than 2.9 V), and enhances at the same time the anti-Electro-Static discharge (ESD) capability (e.g., the ESD passing rate of 8 KV is increased from 60% or more than 90%).

In some embodiments, the first quantum well 102a, the second quantum well 102b, and the third quantum well 102c may also have different materials, depths, element concentration distributions, etc.

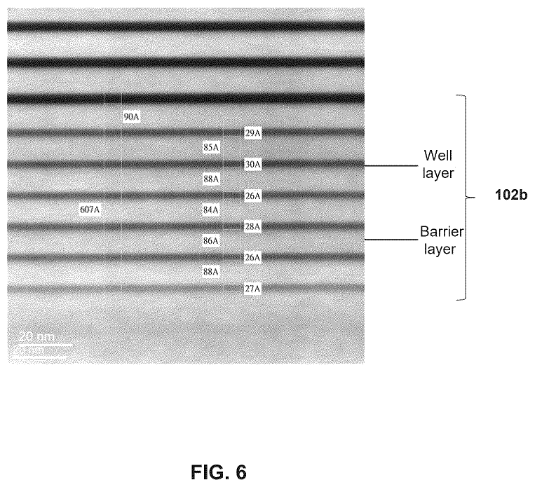

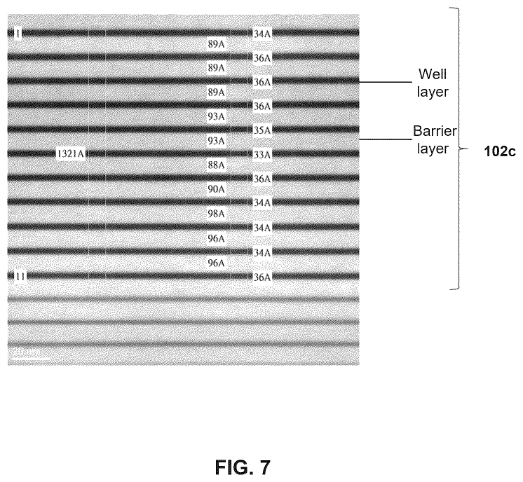

FIG. 5 is a transmission electron microscope (TEM) image of a first quantum well of a semiconductor light-emitting device according to some embodiments of the present disclosure; FIG. 6 is a transmission electron microscope (TEM) image of a second quantum well of a semiconductor light-emitting device according to some embodiments of the present disclosure; and FIG. 7 is a transmission electron microscope (TEM) image of a third quantum well of a semiconductor light-emitting device according to some embodiments of the present disclosure.

In some embodiments, as shown in FIG. 5, a well layer of the first quantum well 102a includes InGaN, GaN, AlGaN, AlInGaN, AlInN, or any combination thereof. A depth of the well layer of the first quantum well 102a is 5 Å˜80 Å. For example, the depth of the well layer of the first quantum well 102a may be 5 Å, 25 Å, 50 Å, or 80 Å. In some embodiments, a barrier layer of the first quantum well 102a includes InGaN, GaN, AlGaN, AlInGaN, AlInN, AlN, or any combination thereof. A depth of the barrier layer of the first quantum well 102a is 10 Å˜500 Å. For example, the depth of the barrier layer of the first quantum well 102a may be 10 Å, 25 Å, 200 Å, or 500 Å.

In some embodiments, an Al element concentration distribution of the first quantum well 102a shows a descending trend in a direction of the Negative-type semiconductor 101, a descending angle of the Al element concentration distribution is v, and an angle range of the v is 15°≤v≤75°. For example, the descending angle v of the Al element concentration distribution may be 15°, 20°, 45°, or 75°.

In some embodiments, a C/O element concentration ratio distribution of the first quantum well 102a is V-shaped, the C/O element concentration ratio distribution shows a descending trend in a direction of the Positive-type semiconductor 104, a descending angle of the C/O element concentration ratio distribution is w, and an angle range of the ω is 20°≤ω≤80°. For example, the descending angle ω of the C/O element concentration ratio distribution may be 20°, 30°, 45°, or 80°.

In some embodiments, the C/O element concentration ratio distribution may include one or more ratios such as a concentration ratio between the C element and the O element or a mass ratio between the C element and the O element.

In some embodiments, as shown in FIG. 6, a well layer of the second quantum well 102b includes InGaN, GaN, AlGaN, AlInGaN, or AlInN, or any combination thereof. A depth of the well layer of the second quantum well 102b is 5 Å˜150 Å. For example, the depth of the well layer of the second quantum well 102b may be 10 Å, 25 Å, 200 Å, or 100 Å.

In some embodiments, a barrier layer of the second quantum well 102b includes InGaN, GaN, AlGaN, AlInGaN, AlInN, AlN, or any combination thereof. A depth of the barrier layer of the second quantum well 102b is 10 Å˜300 Å. For example, the depth of the barrier layer of the second quantum well 102b may be 10 Å, 50 Å, 200 Å, or 300 Å.

In some embodiments, an Al element concentration distribution of the second quantum well 102b shows a descending trend in the direction of the Negative-type semiconductor, a descending angle of the Al element concentration distribution is μ, and an angle range of the μ is 20°≤μ≤80°. For example, the descending angle μ of the Al element concentration distribution may be 20°, 30°, 65°, or 80°.

In some embodiments, a C/O element concentration ratio distribution of the second quantum well 102b is L-shaped, the C/O element concentration ratio distribution shows a descending trend in the direction of the Positive-type semiconductor, and a descending angle of the C/O element concentration ratio distribution is γ, and an angle range of the γ is 25°≤γ≤85°. For example, the descending angle γ of the C/O element concentration ratio distribution may be 25°, 50°, 65°, or 85°.

In some embodiments, as shown in FIG. 7, a well layer of the third quantum well 102c includes InGaN, GaN, AlGaN, AlInGaN, AlInN, or any combination thereof. A depth of the well layer of the third quantum well 102c is 5 Å˜150 Å. For example, the depth of the well layer of the third quantum well 102c may be 5 Å, 50 Å, 80 Å, or 150 Å.

In some embodiments, a barrier layer of the third quantum well 102c includes InGaN, GaN, AlGaN, AlInGaN GaN, AlGaN, AlInGaN, AlInN, AlN, or any combination thereof. A depth of the barrier layer of the third quantum well 102c is 10 Å˜200 Å. For example, the depth of the barrier layer of the third quantum well 102c may be 10 Å, 50 Å, 90 Å, or 200 Å.

In some embodiments, an Al element concentration distribution of the third quantum well 102c shows a descending trend in the direction of the Negative-type semiconductor, a descending angle of the Al element concentration distribution is A, and an angle range of the λ is 30≤λ≤90. For example, the descending angle A of the Al element concentration distribution may be 30°, 50°, 65°, or 90°.

In some embodiments, a C/O element concentration ratio distribution of the third quantum well 102c shows a descending trend in the direction of the Negative-type semiconductor, a descending angle of the C/O element concentration ratio distribution is β, and an angle range of the β is 10°≤β≤70°. For example, the descending angle β of the C/O element concentration ratio distribution may be 10°, 50°, 65°, or 70°.

In some embodiments, a H/O element concentration ratio distribution of the third quantum well 102c shows a descending trend in the direction of the Negative-type semiconductor, a descending angle of the H/O element concentration ratio distribution is K, and an angle range of the K is 20°≤K≤80°. For example, the descending angle K of the H/O element concentration ratio distribution may be 20°, 50°, 60°, or 80°.

In some embodiments, a relationship of the descending angles of the Al/O element concentration distribution of the first quantum well 102a, the second quantum well 102b, and the third quantum well 102c, the descending angles of the C/O element concentration ratio distribution of the first quantum well 102a, the second quantum well 102b, and the third quantum well 102c, and the descending angle of the H/O element concentration ratio distribution of the third quantum well 102c is 10°≤β≤v≤μ≤ω≤K≤γ≤λ≤90°.

Exemplarily, the descending angle v of the Al element concentration distribution of the first quantum well 102a may be 15°, and the descending angle ω of the C/O element concentration ratio distribution of the first quantum well 102a may be 45°; the descending angle μ of the Al element concentration distribution of the second quantum well 102b may be 30°, and the descending angle γ of the C/O element concentration ratio distribution of the second quantum well 102b may be 60°; the descending angle λ of the Al element concentration distribution of the third quantum well 102c may be 90°, the angle β of the C/O element concentration ratio distribution of the third quantum well 102c may be 10°, and the angle K of the H/O element concentration ratio distribution of the third quantum well 102c may be 50°.

In the embodiments of the present disclosure, the element ratio and the angle change of the quantum well may be designed, which enhances the stress release at the interface between the well layer and the barrier layer of the quantum well, reduces the stress at the interface between the well layer and the barrier layer of the quantum well, reduces the stress mismatch and a non-radiative recombination center such as a Shockley-Read-Hall (SRH) recombination or an Auger recombination of the quantum well, enhances the electron overflow barrier and reduces the hole injection barrier, enhances the radiative recombination efficiency of the quantum well, reduces the electron overflow and hole overflow under high-current injection, enhances the quantum localization effect of the quantum well, thereby reducing the efficiency droop of the semiconductor light-emitting device under high-current injection (e.g., reducing the efficiency droop from 40%˜70% to 5%˜35%).

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and modifications are intended to be suggested by this disclosure and are within the spirit and scope of the exemplary embodiments of this disclosure.

These alterations, improvements, and modifications are intended to be suggested by this disclosure and are within the spirit and scope of the exemplary embodiments of this disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the invention. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities, properties, and so forth, used to describe and claim certain embodiments of the application are to be understood as being modified in some instances by the term “about,” “approximate,” or “substantially.” For example, “about,” “approximate,” or “substantially” may indicate±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present disclosure) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A semiconductor light-emitting device, comprising: a substrate, a Negative-type semiconductor, a quantum well, an electron-blocking layer, and a Positive-type semiconductor arranged in a sequential stack, wherein
the quantum well includes a first quantum well, a second quantum well, and a third quantum well; and there are differences among a dielectric constant, a refractive index, a forbidden bandwidth, and an electron effective mass of the first quantum well, a dielectric constant, a refractive index, a forbidden bandwidth, and an electron effective mass of the second quantum well, and a dielectric constant, a refractive index, a forbidden bandwidth, and an electron effective mass of the third quantum well to make dielectric constants, refractive indexes, forbidden bandwidths and electron effective masses of the semiconductor light-emitting device distributed in a gradient in at least one direction; and
the quantum well includes a periodic structure consisting of a well layer and a barrier layer, the periodic structure having a count of periods of 1 to 50; a coefficient of thermal expansion of the well layer is smaller than or equal to a coefficient of thermal expansion of the barrier layer; an elastic coefficient of the well layer is smaller than or equal to an elastic coefficient of the barrier layer; a lattice constant of the well layer is greater than or equal to a lattice constant of the barrier layer; and a coefficient of spontaneous polarization of the well layer is smaller than or equal to a coefficient of spontaneous polarization of the barrier layer.

2. The semiconductor light-emitting device according to claim 1, wherein a dielectric constant of the Negative-type semiconductor is a, a dielectric constant of the well layer of the first quantum well is b, a dielectric constant of the well layer of the second quantum well is c, a dielectric constant of the well layer of the third quantum well is d, and a dielectric constant of the electron-blocking layer is e, a dielectric constant of the Positive-type semiconductor is f, and a gradient relationship of the dielectric constants of the semiconductor light-emitting device is 12≥d≥c≥b≥f≥a≥e≥8.

3. The semiconductor light-emitting device according to claim 1, wherein a refractive index of the Negative-type semiconductor is g, a refractive index of the well layer of the first quantum well is h, a refractive index of the well layer of the second quantum well is i, a refractive index of the well layer of the third quantum well is j, a refractive index of the electron-blocking layer is k, a refractive index of the Positive-type semiconductor is l, and a gradient relationship of the refractive indexes of the semiconductor light-emitting device is 3.5≥j≥i≥h≥l≥g≥k≥1.5.

4. The semiconductor light-emitting device according to claim 1, wherein a forbidden bandwidth of the Negative-type semiconductor is u, a forbidden bandwidth of the well layer of the first quantum well is v, a forbidden bandwidth of the well layer of the second quantum well is w, a forbidden bandwidth of the well layer of the third quantum well is x, a forbidden bandwidth of the electron blocking layer is γ, a forbidden bandwidth of the Positive-type semiconductor is z, and a gradient relationship of the forbidden bandwidths of the semiconductor light-emitting device is 6.5 e≥y≥u≥z≥v≥w≥x≥0.5 eV.

5. The semiconductor light-emitting device according to claim 1, wherein an electron effective mass of the Negative-type semiconductor is o, an electron effective mass of the well layer of the first quantum well is p, an electron effective mass of the well layer of the second quantum well is q, and an electron effective mass of the well layer of the third quantum well is r, an electron effective mass of the electron-blocking layer is s, an electron effective mass of the Positive-type semiconductor is t, and a gradient relationship of the electron effective masses of the semiconductor light-emitting device is 10 mₑ≥s≥o≥t≥p≥q≥r≥0.01 mₑ.

6. The semiconductor light-emitting device according to claim 1, wherein an element concentration distribution of the electron-blocking layer includes a Mg doping concentration distribution, an Al element concentration distribution, an In element concentration distribution, a Si doping concentration distribution, a C element concentration distribution, a H element concentration distribution and an O element concentration distribution in at least one direction;
the Mg doping concentration distribution of the electron-blocking layer is parabolic, a peak position of the Mg doping concentration distribution shows a descending trend in a direction of an interface of the quantum well, a descending angle of the Mg doping concentration distribution is q, and an angle range of the φ is 30°≤φ≤90°;
the Si doping concentration distribution of the electron-blocking layer is W-shaped, the Si doping concentration distribution shows a descending trend in a direction of the quantum well, a descending angle of the Si doping concentration distribution is θ, and an angle range of the θ is 20°≤θ≤85°;
the Al element concentration distribution of the electron-blocking layer is M-shaped, a peak position of the Al element concentration distribution shows a descending trend in the direction of the quantum well, a descending angle of the Al element concentration distribution is α, and an angle range of the α is 10°≤α≤80°;
the In element concentration distribution of the electron-blocking layer is parabolic, a peak position of the In element concentration distribution shows a descending trend in the direction of the quantum well, a descending angle of the In element concentration distribution is ρ, and an angle range of the ρ is 15°≤ρ≤85°;
a peak position of the H element concentration distribution of the electron-blocking layer shows a descending trend in the direction of the quantum well, a descending angle of the H element concentration distribution is ε, and an angle range of the ε is 15°≤ε≤85°;
a peak position of the C element concentration distribution of the electron-blocking layer shows a descending trend in the direction of the quantum well, a descending angle of the C element concentration distribution is δ, and an angle range of the δ is 10°≤δ≤80°; and
a peak position of the O element concentration distribution of the electron-blocking layer shows a descending trend in the direction of the quantum well, a descending angle of the O element concentration distribution is w, and an angle range of the w is 25°≤Ψ≤85°.

7. The semiconductor light-emitting device according to claim 6, wherein a relationship of the descending angles of the electron-blocking layer is 10°≤α≤δ≤ρ≤ε≤θ≤Ψ≤φ≤85°.

8. The semiconductor light-emitting device according to claim 6, wherein an electron effective mass distribution of the electron-blocking layer is V-shaped or M-shaped; a piezoelectric polarization coefficient distribution of the electron-blocking layer is M-shaped; a dielectric constant distribution of the electron-blocking layer is inverted V-shaped; an Al/O element concentration ratio distribution of the electron-blocking layer is M-shaped and an In/O element concentration ratio distribution of the electron-blocking layer is N-shaped; and a Mg/O element concentration ratio distribution of the electron-blocking layer is parabolic.

9. The semiconductor light-emitting device according to claim 1, wherein
the well layer of the first quantum well includes at least one of InGaN, GaN, AlGaN, AlInGaN, or AlInN, and a depth of the well layer of the first quantum well is 5 Å˜80 Å; the barrier layer of the first quantum well includes at least one of InGaN, GaN, AlGaN, AlInGaN GaN, AlGaN, AlInGaN, or AlN, and a depth of the barrier layer of the first quantum well is 10 Å-500 Å; an Al element concentration distribution of the first quantum well shows a descending trend in a direction of the Negative-type semiconductor, a descending angle of the Al element concentration distribution is v, and an angle range of the v is 15°≤v≤75°; and a C/O element concentration ratio distribution of the first quantum well is V-shaped, the C/O element concentration ratio distribution shows a descending trend in a direction of the Positive-type semiconductor, a descending angle of the C/O element concentration ratio distribution is ω, and an angle range of the ω is 20°≤ω≤80°;
the well layer of the second quantum well includes at least one of InGaN, GaN, AlGaN, AlInGaN, or AlInN, and a depth of the well layer of the second quantum well is 5 Å˜100 Å; the barrier layer of the second quantum well includes at least one of InGaN, GaN, AlGaN, AlInGaN, GaN, AlGaN, AlInN, or AlN, and a depth of the barrier layer of the second quantum well is 10 Å˜300 Å; an Al element concentration distribution of the second quantum well shows a descending trend in the direction of the Negative-type semiconductor, a descending angle of the Al element concentration distribution is μ, and an angle range of the μ is 20°≤μ≤80°; and a C/O element concentration ratio distribution of the second quantum well is L-shaped, the C/O element concentration ratio distribution shows a descending trend in the direction of the Positive-type semiconductor, a descending angle of the C/O element concentration ratio distribution is γ, and an angle range of the γ is 25°≤γ≤85°;
the well layer of the third quantum well includes at least one of InGaN, GaN, AlGaN, AlInGaN, or AlInN, and a depth of the well layer of the third quantum well is 5 Å˜150 Å; the barrier layer of the third quantum well includes at least one of InGaN, GaN, AlGaN, AlInGaN GaN, AlGaN, AlInGaN, AlInN, or AlN, and a depth of the barrier layer of the third quantum well is 10 Å˜200 Å; an Al element concentration distribution of the third quantum well shows a descending trend in the direction of the Negative-type semiconductor, a descending angle of the Al element concentration distribution is A, and an angle range of the λ is 30≤λ≤90°; a C/O element concentration ratio distribution of the third quantum well shows a descending trend in the direction of the Negative-type semiconductor, a descending angle of the C/O element concentration ratio distribution is β, and an angle range of the β is 10°≤β≤70°; a H/O element concentration ratio distribution of the third quantum well shows a descending trend in the direction of the Negative-type semiconductor, an descending angle of the H/O element concentration ratio distribution is K, and an angle range of the K is 20≤K≤80°; and
a relationship of the descending angles of the Al/O element concentration distribution of the first quantum well, the second quantum well, and the third quantum well, the descending angles of the C/O element concentration ratio distribution of the first quantum well, the second quantum well, and the third quantum well, and the descending angle of the H/O element concentration ratio distribution of the third quantum well is 10°≤β≤v≤μ≤ω≤k≤γ≤λ≤90°.

10. The semiconductor light-emitting device according to claim 1, wherein the Negative-type semiconductor and the Positive-type semiconductor include at least one of AlGaN, GaN, InGaN, InN, AlInN, AlInGaN, AlN, GaAs, GaP, InP, AlGaAs, AlInGaAs, AlGaInP, InGaAs, InGaAsN, AlInAs, AlInP, AlGaP, InGaP, GaSb, InSb, InAs, InAsSb, AlGaSb, AlSb, InGaSb, AlGaAsSb, InGaAsSb, SiC, Ga₂O₃, or BN; a depth of the Negative-type semiconductor is 5 Å˜80,000 Å, and a depth of the Positive-type semiconductor is 5 Å˜9,000 Å; and the substrate includes at least one of sapphire, silicon, Ge, SiC, AlN, InAs, GaSb, GaN, GaAs, InP, a sapphire/SiO₂ composite substrate, a sapphire/AlN composite substrate, sapphire/SiNx, magnesium-aluminum spinel MgAl₂O₄, MgO, ZnO, ZrB₂, LiAlO₂, or a LiGaO₂ composite substrate.
